(19) United States
(12) Patent Application Publication
(10) Pub. No.: US 2015/0382456 A1
(43) Pub. Date: Dec. 31, 2015

(54) PRINTED CIRCUIT BOARD AND MANUFACTURING METHOD THEREOF

(71) Applicant: FANUC CORPORATION, Yamanashi (JP)

(72) Inventors: Norihiro SAIDOU, Yamanashi (JP); Yuichi OKOUCHI, Yamanashi (JP)

(21) Appl. No.: 14/753,165

(22) Filed: Jun. 29, 2015

(30) Foreign Application Priority Data
Jun. 30, 2014 (JP) 2014-134810

(51) Int. Cl. H05K 1/02; H05K 3/34; H05K 1/18

(52) U.S. Cl. CPC H05K 1/0284; H05K 1/181; H05K 3/3452; H05K 2201/10015; H05K 2201/10022; H05K 2201/10166; H05K 2201/0355

(57) ABSTRACT

A printed circuit board including a metal conductor formed on a surface of an insulating base material and having a component mounting portion, and a solder resist covering a part of the metal conductor, includes a thinned part on a component-mounting-portion side in the solder resist.

### BACKGROUND OF THE INVENTION

1. Field of the Invention

The present invention relates to a printed circuit board on which an electronic component such as an LSI, a capacitor, and a resistor is mounted, and a manufacturing method thereof.

2. Description of the Related Art

FIG. 9 is a view to describe a sectional structure of a conventional printed circuit board. In a printed circuit board 1, metal conductors 3, 5 such as copper foils are formed as a wiring pattern on a surface of an insulating base material 4. The metal conductor 5 serves as a component mounting portion to which an electronic component is electrically connected. A solder resist 2 is formed on a surface of the metal conductor 3 except the component mounting portion.

In a manufacturing process of the printed circuit board, a coating process by use of solder, a so-called solder coating process is generally performed on the metal conductor 5 serving as the component mounting portion, in order to protect a surface thereof and to secure solderability with respect to the electronic component.

Due to downsizing and high function of an electronic device, microfabrication of a printed circuit board constituting the electronic device is being promoted. In association with this, that component mounting portion of the metal conductor which is a target for the solder coating process is also microfabricated, which causes such a problem that wettability of a solder coat cannot be secured sufficiently. Particularly, in a case where a lead-free solder containing no lead is used as the solder coat, its surface tension is larger than that of a conventional Sn—Pb solder containing Sn and Pb as a main components, so that the above problem is more remarkable.

In view of this, as one method to improve the wettability of the solder coat, Japanese Patent Application Publication No. 5-55729 describes a method in which electroless plating is performed on a surface of a metal conductor before a solder coating process is performed, so as to form a Ni layer. However, in this method, the number of manufacturing steps is increased, so that the method has a difficulty in a manufacturing cost and man-hours. Further, as another method, there is such a method in which a solder resist is formed to be thin. When the solder resist is formed to be thin, a solder coat can make contact with a metal conductor, which improves wettability of the solder coat.

However, in the above method, chemical corrosion and electrolytic corrosion may occur depending on an environment where a printed circuit board is placed, which may become a problem. For example, under a factory environment in which equipment such as a machine tool is used, oil smoke and mist due to cutting fluid caused by machining of a work (workpiece) are attached to a surface of the printed circuit board. The oil smoke and mist cause chemical corrosion and electrolytic corrosion in a metal conductor formed on the printed circuit board, which may cause disconnection failure and insulation failure of the printed circuit board. Particularly, in a case where a solder resist of the printed circuit board is thin, chemical corrosion and electrolytic corrosion are easy to occur in the metal conductor formed right under the solder resist. Accordingly, in terms of the printed circuit board used under the factory environment, its solder resist cannot be formed to be thin.

### SUMMARY OF THE INVENTION

In view of this, an object of the present invention is to provide a printed circuit board which improve wettability of a solder coat with respect to a component mounting portion of a microfabricated metal conductor and which has an excellent corrosion resistance, and a manufacturing method thereof.

In the present invention, that part of a solder resist which is near a component mounting portion of a metal conductor is made thinner than the other part of the solder resist, and the other part of the solder resist is configured such that a sufficient thickness is secured on a surface of the metal conductor so that a good corrosion resistance can be obtained.

A printed circuit board of the present invention is a printed circuit board including an insulating base material, a metal conductor formed on a surface of the insulating base material and having a component mounting portion to which an electronic component is electrically connected, and a solder resist covering a part of the metal conductor, and a thinned part formed on a component-mounting-portion side and having a thickness thinner than the other part thereof, in the solder resist.

A thickness of that part the solder resist which is near the component mounting portion may be thinner than a thickness of the metal conductor.

A manufacturing method of a printed circuit board according to the present invention is a method for manufacturing a printed circuit board including an insulating base material, a metal conductor formed on a surface of the insulating base material and having a component mounting portion to which an electronic component is electrically connected, and a solder resist covering a part of the metal conductor, and includes: a first step of forming a solder resist having an opening at a position corresponding to the component mounting portion of the metal conductor and having a thickness thinner than a thickness of the metal conductor; and a second step of forming a solder resist covering a part of the metal conductor, the solder resist having an opening larger than the opening of the solder resist formed in the first step, at the position corresponding to the component mounting portion of the metal conductor. Since the present invention includes the above configuration/steps, it is possible to provide a printed circuit board which can improve wettability of a solder coat with respect to a component mounting portion of a microfabricated metal conductor and which has an excellent corrosion resistance, and a manufacturing method thereof.

### BRIEF DESCRIPTION OF THE DRAWINGS

The above and other objects and features of the present invention will be obvious from the ensuing description of embodiments with reference to the accompanying drawings, in which:

FIG. 1 is a view to describe a printed circuit board according to one embodiment of the present invention, in which that part of a solder resist which is near a component mounting portion of a metal conductor is made thinner than a thickness of the other part of the solder resist;

FIG. 2 is a view to describe a sectional structure of a printed circuit board according to one embodiment of the present invention which printed circuit board has a solder resist structure similar to that in FIG. 1 and includes a wiring portion connected to a component mounting portion of a metal conductor (a wire is drawn out from one side of the component mounting portion of the metal conductor);

FIG. 3 is a view to describe a sectional structure of a printed circuit board according to one embodiment of the present invention which printed circuit board has a solder resist structure similar to that in FIG. 1 and includes wiring portions connected to a component mounting portion of a metal conductor (wires are drawn out from both sides of the component mounting portion of the metal conductor);

FIG. 4 is a view of a printed circuit board according to one embodiment of the present invention, in which that part of a solder resist which is near a component mounting portion of a metal conductor has a thickness of not more than a thickness of a metal conductor;

FIG. 5 is a view to describe a sectional structure of a printed circuit board according to one embodiment of the present invention which printed circuit board has a solder resist structure similar to that in FIG. 4 and includes a wiring portion connected to a component mounting portion of a metal conductor (a wire is drawn out from one side of the component mounting portion of the metal conductor);

FIG. 6 is a view to describe a sectional structure of a printed circuit board according to one embodiment of the present invention which printed circuit board has a solder resist structure similar to that in FIG. 4 and includes wiring portions connected to a component mounting portion of a metal conductor (wires are drawn out from both sides of the component mounting portion of the metal conductor);

FIG. 7 is a view to describe a first step in a manufacturing method of a printed circuit board according to one embodiment of the present invention;

FIG. 8 is a view to describe a second step in the manufacturing method of a printed circuit board according to one embodiment of the present invention; and

FIG. 9 is a view to describe a sectional structure of a conventional printed circuit board.

### DETAILED DESCRIPTION OF THE PREFERRED EMBODIMENTS

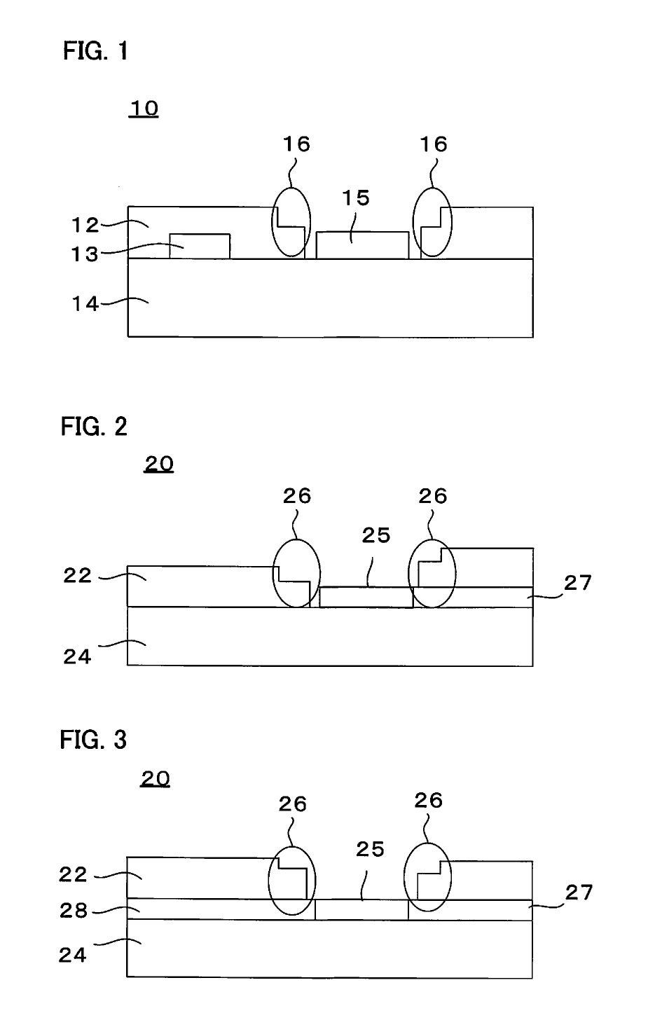

FIG. 1 is a view to describe a printed circuit board according to one embodiment of the present invention, in which that part of a solder resist which is near a component mounting portion of a metal conductor is made thinner than a thickness of the other part of the solder resist.

A printed circuit board 10 is configured such that a metal conductor such as a copper foil is attached to a surface of an insulating base material 14. An etching resist is applied to a surface of the metal conductor, and then pattern formation of the etching resist is performed by exposure/developing so that only that part of the etching resist which is desired to be left as a wiring pattern is left and the other part of the etching resist is removed. Subsequently, only that part of the metal conductor which is not covered with the etching resist is selectively removed by etchant with the etching resist thus formed in a pattern being used as a protective coat, and then, the etching resist is removed. Hereby, the wiring pattern (metal conductors 13, 15) is formed. Note that a formation method of the wiring pattern is not limited to the above method.

A solder resist 12 serving as a protective layer that protects the metal conductor 13 is formed on the metal conductor formed as the wiring pattern except that part of the metal conductor which serves as a component mounting portion (a component mounting portion 15 of the metal conductor). At this time, a sufficient thickness is secured as a thickness of the solder resist on the surface of the metal conductor 13 except the component mounting portion. In the meantime, that part of the solder resist 12 which is in a component-mounting-portion vicinal area 16 near the metal conductor 15 serving as the component mounting portion is made thinner than the other part thereof.

It is preferable for that thinned part 16 of the solder resist 12 which is on a component-mounting-portion side to be provided with a width of not less than 10 gm from a resist opening end (but within a range in which the thinned part 16 does not overlap with its vicinal metal conductor except the component mounting portion). When that part of the solder resist 12 which is in the thinned part 16 on the component-mounting-portion side is made thinner than the other part, a solder coat can make contact with the metal conductor, thereby improving wettability of the solder coat. In the other part of the solder resist 12, a sufficient thickness is secured on the surface of the metal conductor, so that a good corrosion resistance can be obtained.

One embodiment of the present invention encompasses a printed circuit board including a wiring portion connected to the component mounting portion 15 of the metal conductor. A printed circuit board 20, illustrated in FIG. 2, according to one embodiment of the present invention includes a solder resist 22 having a structure similar to that in the printed circuit board 10 illustrated in FIG. 1, and includes a wiring portion 27 connected to a component mounting portion 25 of a metal conductor (a wire is drawn out from one side of the component mounting portion 25 of the metal conductor). Note that a reference sign 26 indicates a thinned part on a component-mounting-portion side.

A printed circuit board, illustrated in FIG. 3, according to one embodiment of the present invention includes a solder resist 22 having a structure similar to that in the printed circuit board 10 illustrated in FIG. 1, and includes wiring portions 27, 28 connected to a component mounting portion 25 of a metal conductor (wires are drawn out from both sides of the component mounting portion 25 of the metal conductor). A reference sign 24 indicates an insulating base material.

Note that the wiring portions 27, 28 are made of the same metallic material as the component mounting portion 25 of the metal conductor.

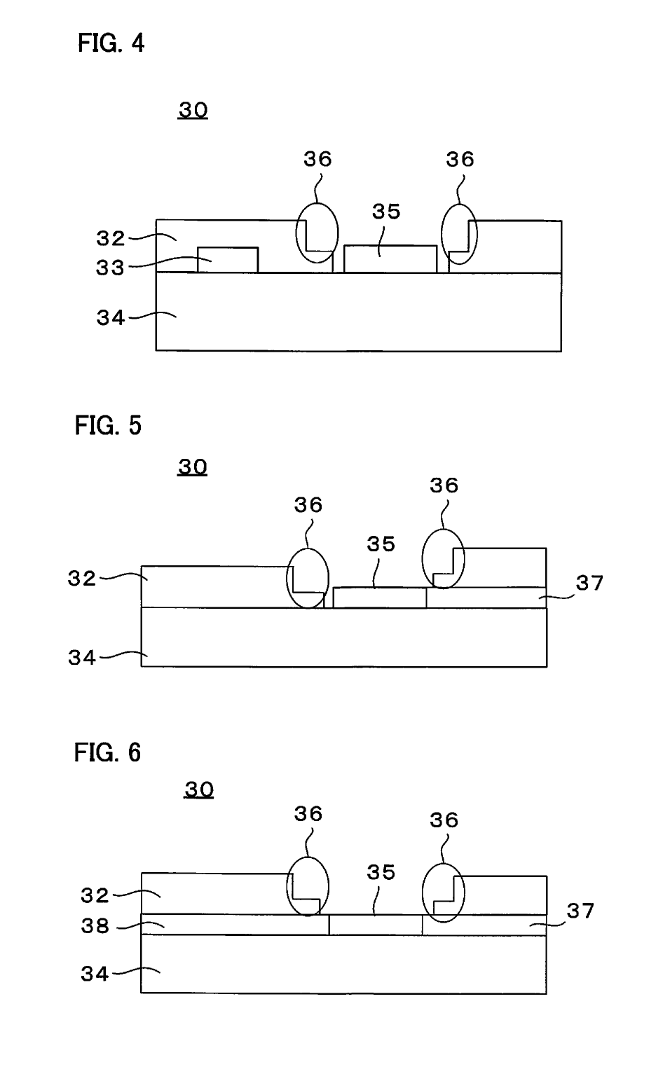

FIG. 4 is a view of a printed circuit board according to one embodiment of the present invention, in which that part of a solder resist which is near a component mounting portion of a metal conductor has a thickness of not more than a thickness of the metal conductor. It is preferable that a thickness of that part of a solder resist 32 which is in a thinned part 36 on a side closer to the component mounting portion of the metal conductor have a thickness thinner than that of the metal conductor, and a thickness of the other part of the solder resist 32 have a sufficient thickness on a surface of the metal conductor in consideration of corrosion resistance.

One embodiment of the present invention encompasses a printed circuit board including a wiring portion connected to the component mounting portion 35 of the metal conductor. A printed circuit board 30, illustrated in FIG. 5, according to one embodiment of the present invention includes a solder resist 32 having a structure similar to that in FIG. 4, and includes a wiring portion 37 connected to a component mounting portion 35 of a metal conductor (a wire is drawn out from one side of the component mounting portion 35 of the metal conductor).

A printed circuit board 30, illustrated in FIG. 6, according to one embodiment of the present invention includes a solder resist 32 having a structure similar to that in FIG. 4, and includes wiring portions 37, 38 connected to a component mounting portion 35 of a metal conductor (wires are drawn out from both sides of the component mounting portion of the metal conductor).

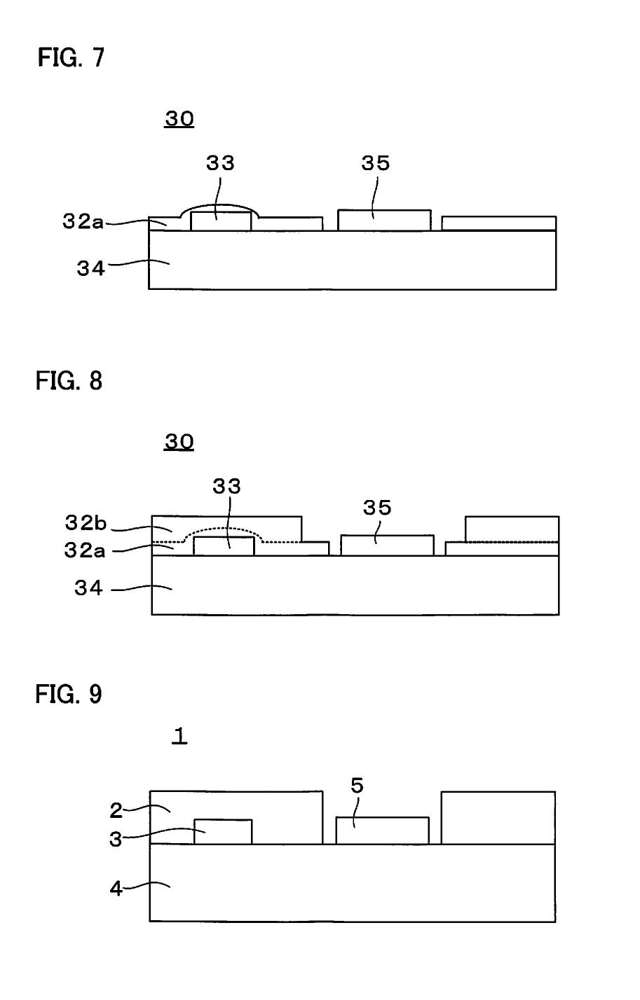

Next will be described a manufacturing method of a printed circuit board, with reference to FIGS. 7, 8. FIG. 7 is a view to describe a first step in a manufacturing method of a printed circuit board according to one embodiment of the present invention. FIG. 8 is a view to describe a second step in the manufacturing method of a printed circuit board according to one embodiment of the present invention.

A method, according to one embodiment of the present invention, for manufacturing a printed circuit board including an insulating base material 34, a metal conductor 35 formed on a surface of the insulating base material 34 and having a component mounting portion to which an electronic component is electrically connected, and a solder resist covering a part of the metal conductor includes: a first step of forming a first solder resist 32a having an opening at a position corresponding to the component mounting portion of the metal conductor and having a thickness thinner than a thickness of the metal conductor; and a second step of forming a second solder resist 32b having an opening larger than the opening of the first solder resist 32a formed in the first step, at the position corresponding to the component mounting portion of the metal conductor. Solder resist layers formed in the first step and the second step are formed in the same manner as a conventional solder resist layer. Since the first solder resist 32a and the second solder resist 32b are made of the same material, no problem is cased in terms of adherence. Note that the second solder resist 32b formed in the second step is formed so as to be laminated on the first solder resist 32a formed in the first step, so that the second solder resist 32b covers an area except the component mounting portion 35.

1. A printed circuit board including, an insulating base material, a metal conductor formed on a surface of the insulating base material and having a component mounting portion to which an electronic component is electrically connected, and a solder resist covering a part of the metal conductor, comprising:
a thinned part formed on a component-mounting-portion side and having a thickness thinner than the other part thereof, in the solder resist.

2. The printed circuit board according to claim 1, wherein
a thickness of that part of the solder resist which is near the component mounting portion is thinner than a thickness of the metal conductor.

3. A method for manufacturing a printed circuit board including an insulating base material, a metal conductor formed on a surface of the insulating base material and having a component mounting portion to which an electronic component is electrically connected, and a solder resist covering a part of the metal conductor, the method comprising:
a first step of forming a solder resist having an opening at a position corresponding to the component mounting portion of the metal conductor and having a thickness thinner than a thickness of the metal conductor; and
a second step of forming a solder resist covering a part of the metal conductor, the solder resist having an opening larger than the opening of the solder resist formed in the first step, at the position corresponding to the component mounting portion of the metal conductor.
